(19) United States
(12) Patent Application Publication
(10) Pub. No.: US 2026/0223352 A1
(43) Pub. Date: Jul. 30, 2026

(54) Integrated Circuit Construction, DRAM Circuitry, Method Used In Forming Integrated Circuitry, And Method Used In Forming DRAM Circuitry

(71) Applicant: Micron Technology, Inc., Boise, ID (US)

(72) Inventors: Jun Ho Lee, Meridian, ID (US); Yen Ting Lin, Boise, ID (US); Byung Yoon Kim, Boise, ID (US); Vinay Nair, Boise, ID (US)

(73) Assignee: Micron Technology, Inc., Boise, ID (US)

(21) Appl. No.: 19/366,104

(22) Filed: Oct. 22, 2025

Related U.S. Application Data
(60) Provisional application No. 63/750,443, filed on Jan. 28, 2025.

(51) Int. Cl. H10B 12/00

(52) U.S. Cl. CPC H10B 12/09; H10B 12/315; H10B 12/50

(57) ABSTRACT

An integrated circuit construction comprises conductive vias that are individually directly above and directly electrically coupled to individual operative transistors. Insulator islands individually extend upwardly from individual inoperative transistors. Insulating material surrounds individual of the insulator islands and individual of the conductive vias. Insulative material is directly above the insulating material. Conducting vias individually extend through the insulative material. Some of the conducting vias are directly above and directly against individual of the conductive vias. Another some of the conducting vias are directly above individual of the insulator islands. Other embodiments, including method, are disclosed.

### TECHNICAL FIELD

Embodiments disclosed herein pertain to integrated circuit constructions, to DRAM circuitry, to methods used in forming integrated circuitry, and to methods used in forming DRAM circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The digitlines may conductively interconnect memory cells along columns of the array, and the access lines may conductively interconnect memory cells along rows of the array. Each memory cell may be uniquely addressed through the combination of a digitline and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1. In other systems, at least some individual memory cells may be configured to store more than two levels or states of information.

A capacitor is one type of electronic component that may be used in a memory cell. A capacitor has two electrical conductors separated by electrically insulating material. Energy as an electric field may be electrostatically stored within such material. Depending on composition of the insulator material, that stored field will be volatile or non-volatile. For example, a capacitor insulator material including only SiO₂ will be volatile. One type of non-volatile capacitor is a ferroelectric capacitor which has ferroelectric material as at least part of the insulating material. Ferroelectric materials are characterized by having two stable polarized states and thereby can comprise programmable material of a capacitor and/or memory cell. The polarization state of the ferroelectric material can be changed by application of suitable programming voltages and remains after removal of the programming voltage (at least for a time). Each polarization state has a different charge-stored capacitance from the other, and which ideally can be used to write (i.e., store) and read a memory state without reversing the polarization state until such is desired to be reversed. Less desirable, in some memory having ferroelectric capacitors the act of reading the memory state can reverse the polarization. Accordingly, upon determining the polarization state, a re-write of the memory cell is conducted to put the memory cell into the pre-read state immediately after its determination. Regardless, a memory cell incorporating a ferroelectric capacitor ideally is non-volatile due to the bi-stable characteristics of the ferroelectric material that forms a part of the capacitor. Other programmable materials may be used as a capacitor insulator to render capacitors non-volatile.

A field effect transistor is another type of electronic component that may be used in a memory cell. These transistors comprise a pair of conductive source/drain regions having a semiconductive channel region there-between. A conductive gate is adjacent the channel region and separated there-from by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate. Regardless, the gate insulator may be programmable, for example being ferroelectric. One type of memory cell has at least one transistor and at least one capacitor (e.g., a DRAM cell).

Capacitors and transistors may of course be used in integrated circuitry other than memory circuitry.

### BRIEF DESCRIPTION OF THE DRAWINGS

FIG. 1 is a diagrammatic sectional view of a construction in process in accordance with some embodiments of the invention.

FIGS. 2-10 are various sectional views of the FIG. 1 construction as indicated.

FIGS. 11-28 are diagrammatic sequential sectional views of the construction of FIGS. 1-10 in process in accordance with some embodiments of the invention.

### DETAILED DESCRIPTION OF EXAMPLE EMBODIMENTS

Embodiments of the invention encompass methods used in forming integrated circuitry, for example DRAM circuitry, as well as integrated circuitry (e.g., DRAM circuitry) independent of method of manufacture. Example method embodiments of forming DRAM circuitry are first described.

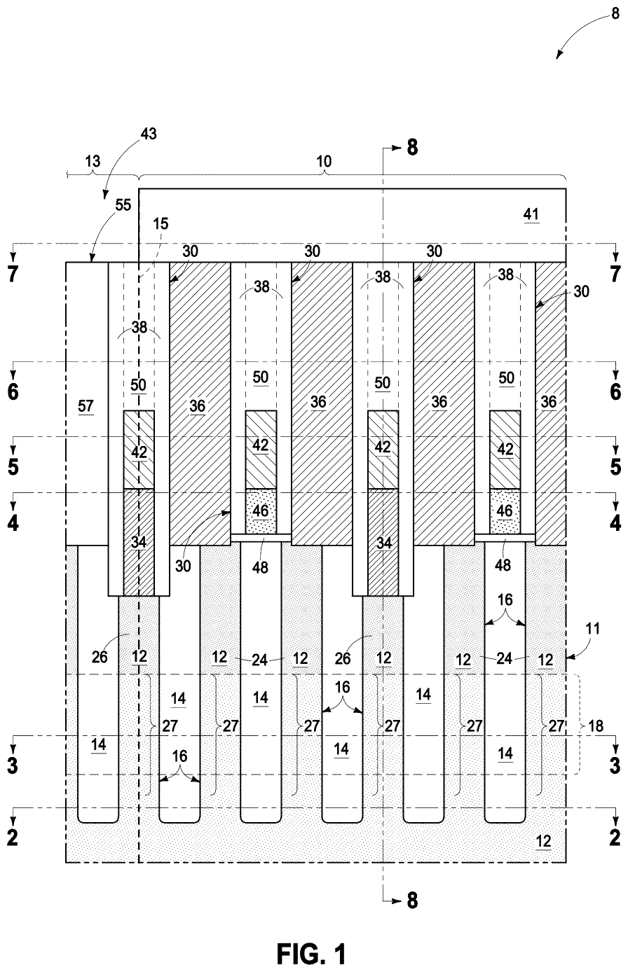

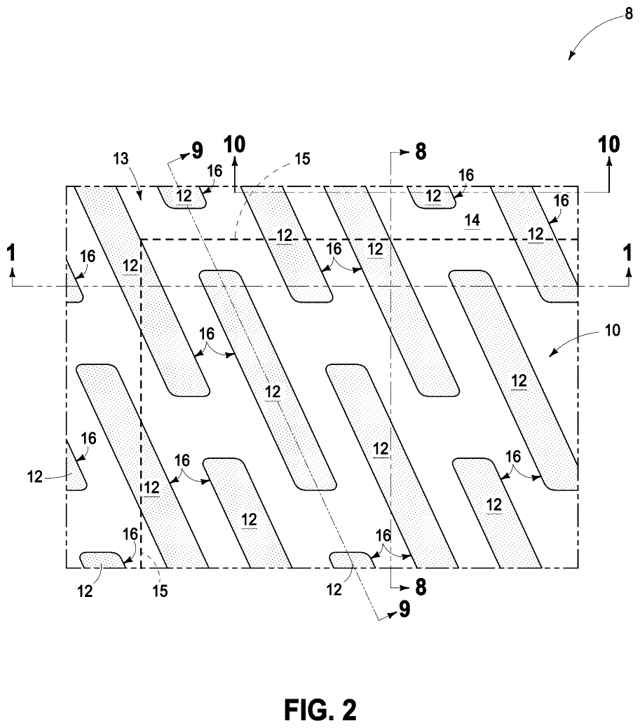

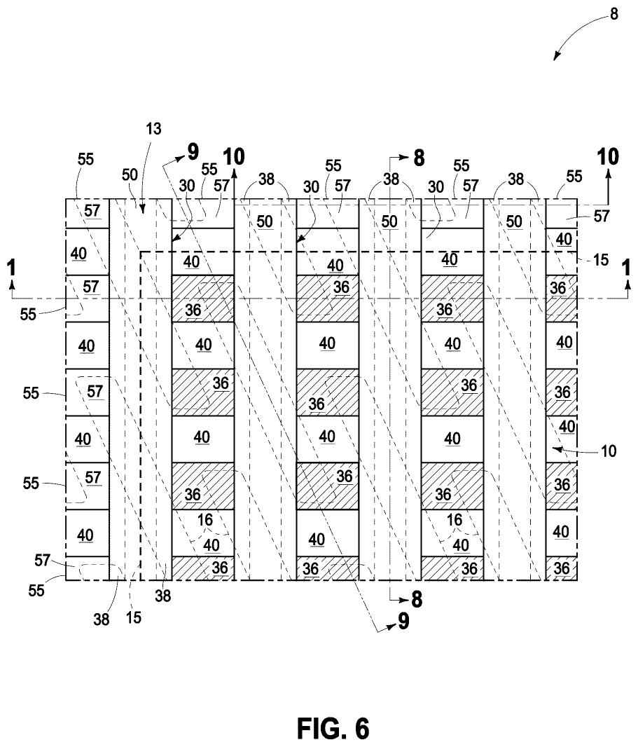

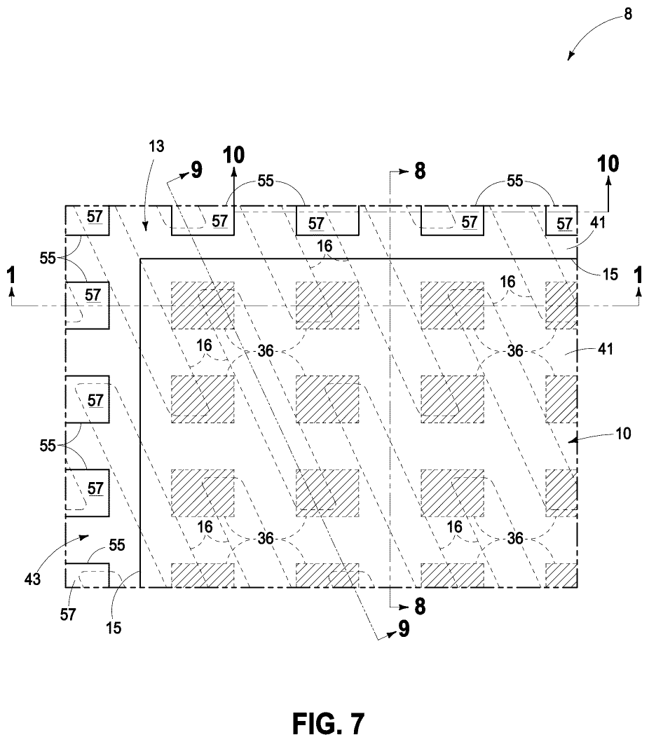

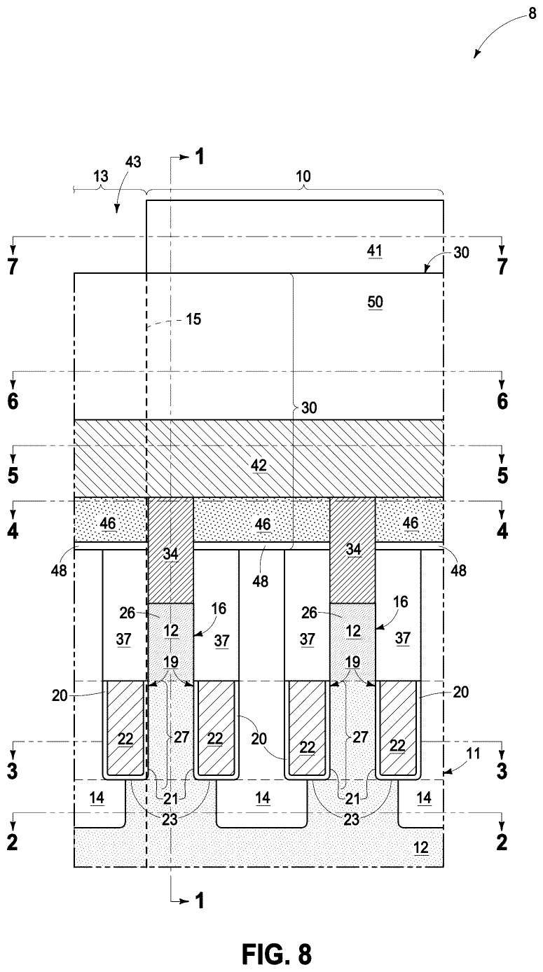

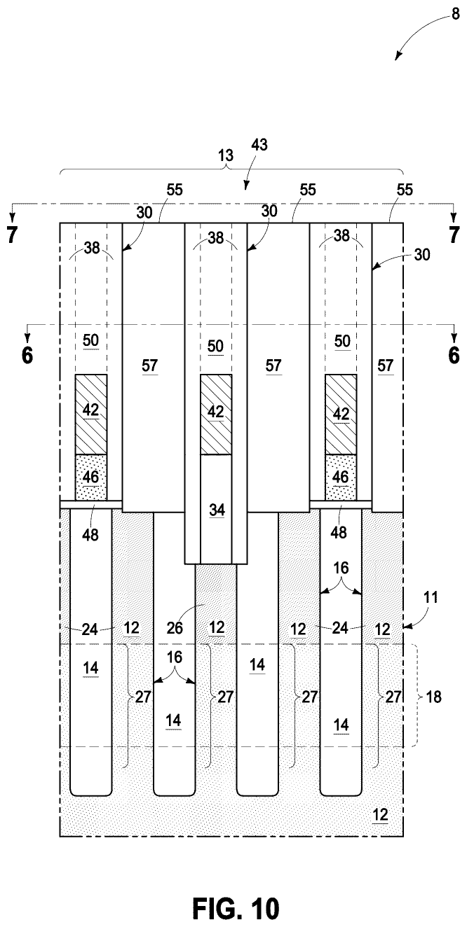

Referring to FIGS. 1-10, an example fragment of a construction 8 has been fabricated. Such comprises a memory-array region 10 and a peripheral region 13 adjacent thereto (a diagrammatic line 15 being used to delineate between regions 10 and 13, although such may or may not be perceptible). Regions 10 and 13 have been fabricated relative to a base or semiconductor substrate 11 that may comprise any one or more of conductive/conductor/conducting (i.e., electrically herein), semiconductive/semiconductor/semiconducting, and insulative/insulator/insulating (i.e., electrically herein) materials. Various materials are above base substrate 11. Materials may be aside, elevationally inward, or elevationally outward of the FIGS. 1-10—depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array.

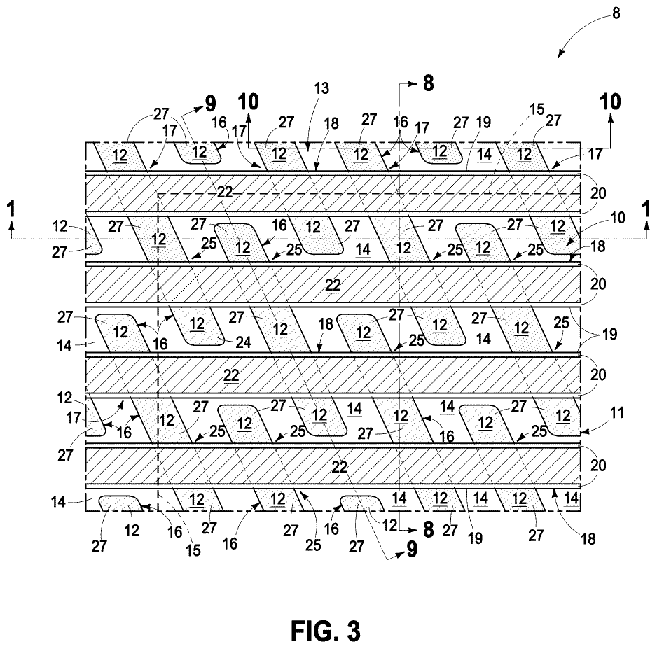

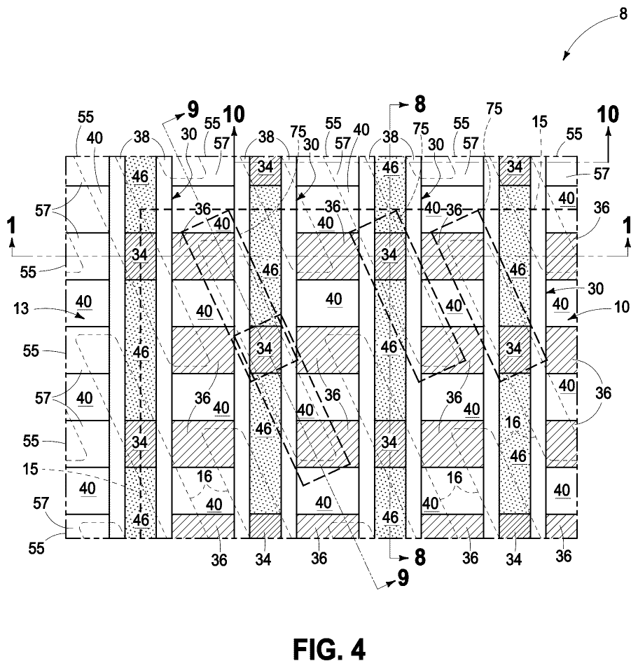

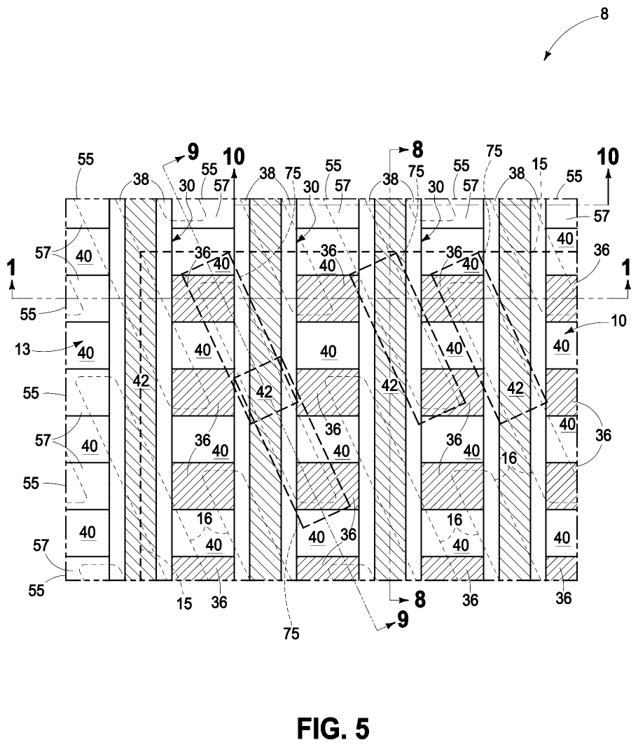

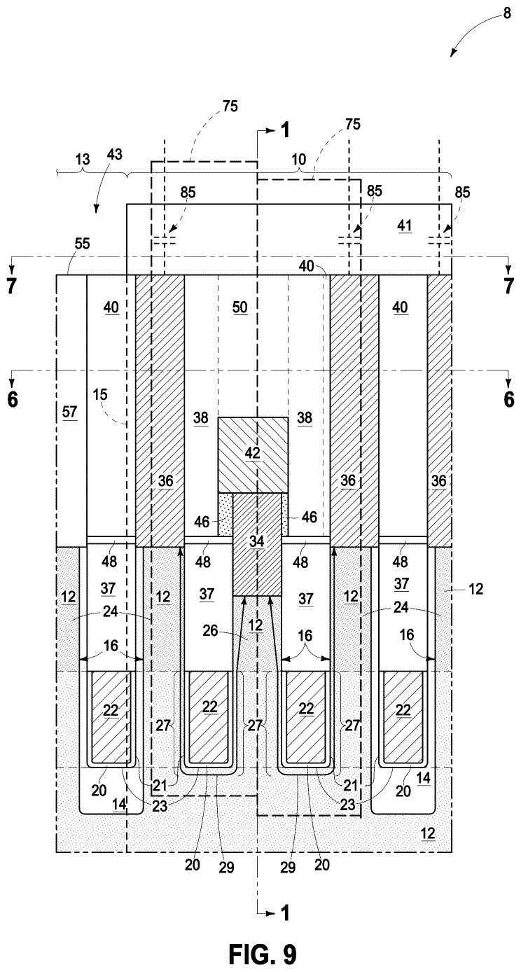

Substrate 11 comprises semiconductive material 12 (e.g., appropriately and variously doped monocrystalline and/or polycrystalline silicon, Ge, SiGe, GaAs, and/or other existing or future-developed semiconductive material), trench isolation regions 14 (e.g., silicon nitride and/or silicon dioxide), and active area regions 16 comprising suitably and variously-doped semiconductive material 12. In one embodiment, construction 8 will comprise operative DRAM cells occupying space within outlines 75 (only two outlines 75 shown in FIG. 9, and only four outlines 75 shown in FIGS. 4 and 5, for clarity in such figures). The operative DRAM cells individually comprise an operative DRAM-cell transistor 25 (i.e., a field effect transistor FIG. 3) within semiconductive material 12 of substrate 11 in memory-array region 10. The operative DRAM cells will also individually comprise a charge-storage device 85 (e.g., a capacitor FIG. 9). However, embodiments of the invention encompass fabricating of other memory cells and other constructions of integrated circuitry independent of whether containing memory cells. Dummy/Inoperative transistors 17 (FIG. 3) are in peripheral region 13. Herein, something is “dummy” if it is always circuit-inoperative, for example meaning no current flow there-through even if the something is conductive and which may be a circuit inoperable dead end that is not part of a current flow path of a circuit even if extending to or from an operative electronic component. As used herein, “inoperative” means always inoperative.

Example transistors 17, 25 are in the form of recessed access devices (a type of construction of a field effect transistor), with example construction 8 showing such recessed access devices grouped in individual pairs of such devices/transistors. Individual transistors 17, 25 include a buried access line construction 18, for example that is within a trench 19 in semiconductive material 12. Constructions 18 comprise conductive gate material 22 (e.g., conductively-doped semiconductor material and/or conductive metal material) that functions as an operative conductive gate of individual transistors 25 and is dummy with respect to dummy transistors 17. A gate insulator 20 (e.g., silicon dioxide and/or silicon nitride) is along sidewalls 21 and a base 23 of individual trenches 19 between conductive gate material 22 and semiconductive material 12. Insulator material 37 (e.g., silicon dioxide and/or silicon nitride) is within trenches 19 above materials 20 and 22. Example individual transistors 17 and 25 comprise a pair of source/drain regions 24, 26 in upper portions of semiconductive material 12 on opposing sides of individual trenches 19 (e.g., regions 24, 26 being laterally outward of and higher than access line constructions 18). Each of source/drain regions 24, 26 comprises at least a part thereof having a conductivity-increasing dopant therein that is of maximum concentration of such conductivity-increasing dopant within the respective source/drain region 24, 26, for example to render such part to be conductive (e.g., having a maximum dopant concentration of at least 10¹⁹ atoms/cm³). Accordingly, all or only a part of each source/drain region 24, 26 may have such maximum concentration of conductivity-increasing dopant. Source/drain regions 24 and/or 26 may include other doped regions (not shown), for example halo regions, LDD regions, etc.

One of the source/drain regions (e.g., region 26) of the pair of source/drain regions in individual of the pairs of example transistors 17, 25 is laterally between conductive gate material 22 and is shared by the pair of transistors 17 or 25. The other of the source/drain regions (e.g., regions 24) of the pair of source/drain regions is not shared by the pair of transistors 17 or 25. Thus, in the example embodiment, each active area region 16 comprises two transistors 17 or 25 (e.g., one pair of transistors 17 or 25), with each sharing a central source/drain region 26.

A channel region 27 is in semiconductive material 12 below pair of source/drain regions 24, 26 along trench sidewalls 21 and around trench base 23. Channel region 27 may be suitably doped with a conductivity-increasing dopant likely of the opposite conductivity-type of the dopant in source/drain regions 24, 26, and for example that is at a maximum concentration in the channel of no greater than 1×10¹⁷ atoms/cm³. When suitable voltage is applied to gate material 22 of an access line construction 18, a conductive channel forms (e.g., along a channel current-flow line/path 29 FIG. 9) within channel region 27 proximate gate insulator 20 such that current is capable of flowing between a pair of source/drain regions 24 and 26 under the access line construction 18 within an individual active area region 16. Stippling is diagrammatically shown to indicate primary conductivity-modifying dopant concentration (regardless of type), with denser stippling indicating greater dopant concentration and lighter stippling indicating lower dopant concentration. Conductivity-modifying dopant may be, and would likely be, in other portions of material 12 as shown. Only two different stippling densities are shown in material 12 for convenience, and additional dopant concentrations may be used and constant dopant concentration is not required in any region.

Digitlines are directly above and individually directly electrically coupled to one of the two source/drain regions (e.g., 26) of multiple of operative DRAM-cell transistors 25, with the digitlines extending from memory-array region 10 into peripheral region 13 and being directly above inoperative transistors 17. As an example, digitline structures 30 have been formed that individually comprise conductive material 42 (e.g., the actual digitline). Conductive vias 34 (e.g., conductive metal material and/or conductively-doped semiconductive material) are spaced longitudinally along digitline structures 30 and individually directly electrically couple the conductive material of digitlines 42 to individual of shared source/drain regions 26 of individual transistors 25. Example digitline structures 30 comprise insulating material 50 (e.g., silicon nitride and/or silicon dioxide) above digitlines 42 and insulating material 38 (e.g., silicon nitride and/or silicon dioxide). Example digitline structures 30 also comprise doped or undoped semiconductor material 46 (example thickness of 25 to 250 Angstroms) between immediately-longitudinally-adjacent conductive vias 34. Example digitline structures 30 also comprise a lower insulative material 48 (e.g., one or more of silicon dioxide, silicon nitride, aluminum dioxide, hafnium oxide, etc., of an example thickness of 50 to 200 Angstroms) below semiconductor material 46 between immediately-longitudinally-adjacent conductive vias 34. As alternate examples, material 46 may comprise insulative material or conductive metal material or be eliminated with the conductive material of digitlines 42 extending inwardly to lower insulative material 48 (not shown).

A pair of capacitors (e.g., dashed lines designated as 85 in FIG. 9, but not-yet-fabricated) will individually directly electrically couple to one of the other source/drain regions 24 in the individual pairs of devices 25. Such occurs through conductive vias 36 (same or different composition from that of vias 34) that are individually directly above and directly electrically coupled to the other of the two source/drain regions (e.g., 24) of one of operative DRAM-cell transistors 25 in memory-array region 10. Insulating material 40 (e.g., silicon dioxide and/or silicon nitride) may be between immediately adjacent conductive via 36 as shown.

Insulative islands 55 are in peripheral region 13 and individually extend from directly above individual of inoperative transistors 17 to above and aside digitlines 42 in peripheral region 13. Insulating material 38/50/40 surrounds insulative islands 55 and conductive vias 34, 36, with such insulating material in some embodiments being of different composition from that of insulative material 57 of insulative islands 55. In one embodiment, insulative material 57 is silicon dioxide and insulating material 38/50/40 is silicon nitride.

In one embodiment, masking material 41 (e.g., photoresist) has been formed in memory-array region 10. Masking material 41 is directly above memory-cell transistors 25 in memory-array region 10. In one embodiment and as shown, masking material 41 completely covers all of memory-array region 10. Some of masking material 41 may be formed in peripheral region 13 (not shown). In one embodiment, none of masking material 41 is in peripheral region 13 (as shown). Regardless, masking material 41 when used has an opening 43 therethrough (at least one) in peripheral region 13 that extends to insulative material 57 of insulative islands 55.

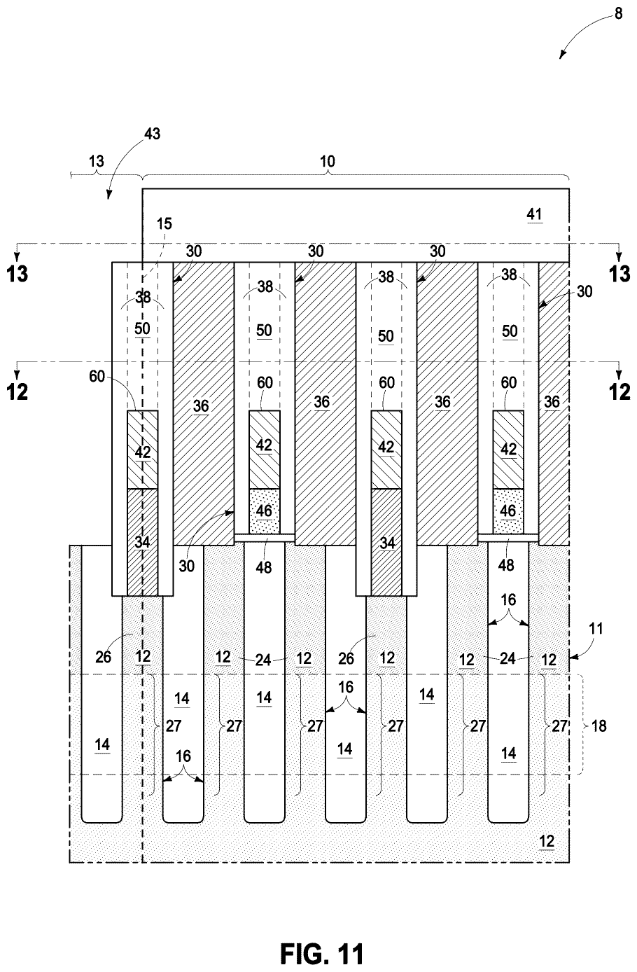

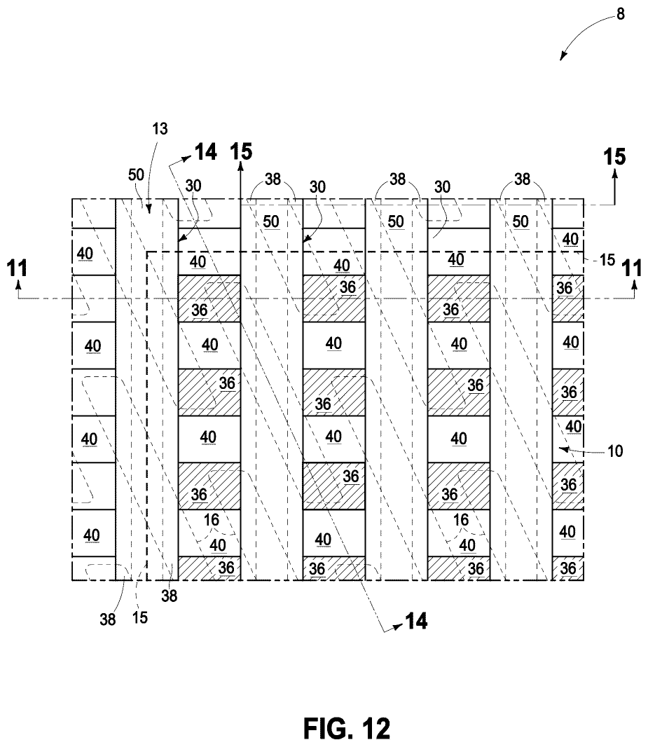

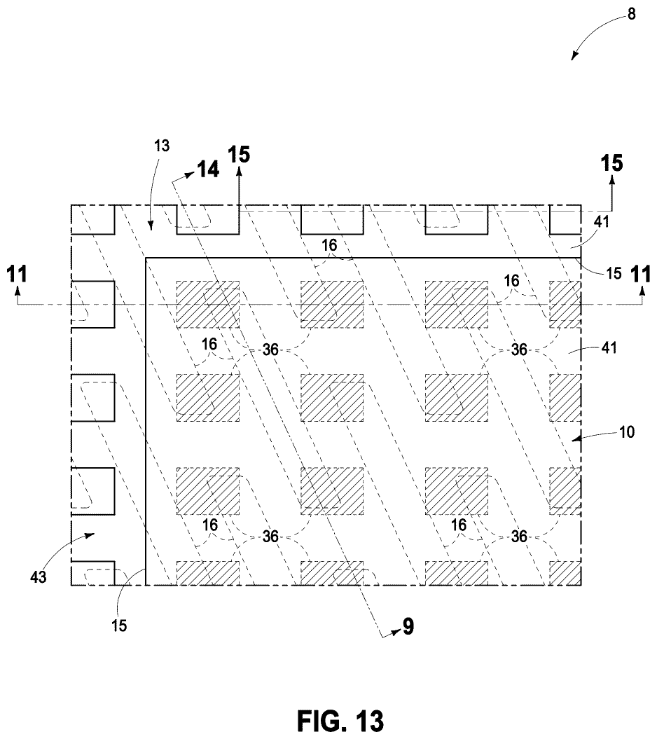

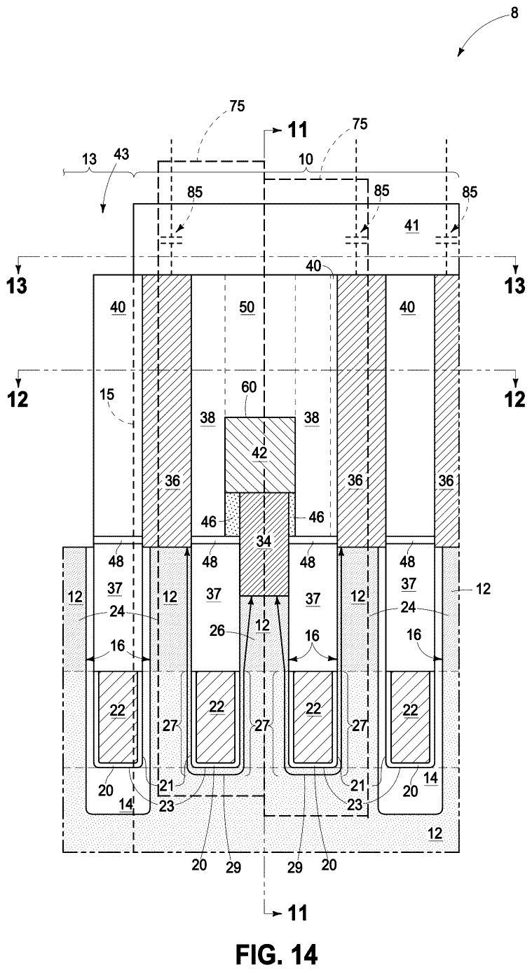

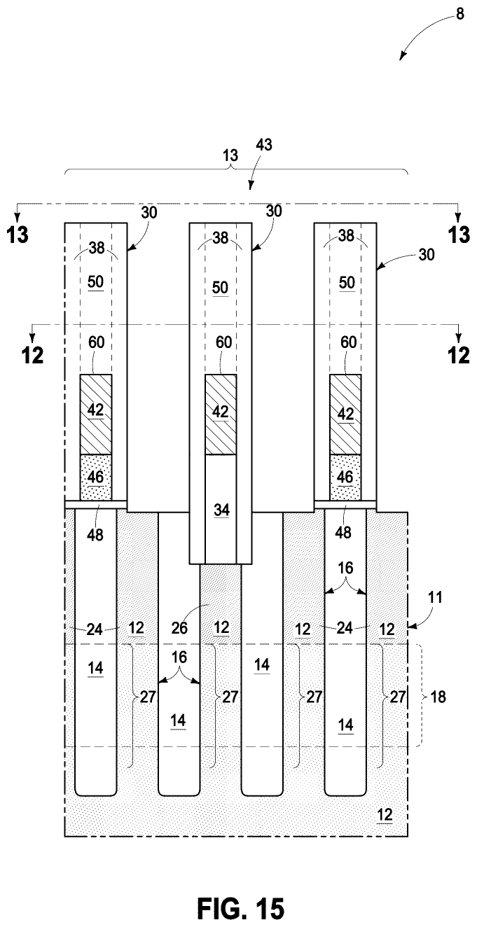

Referring to FIGS. 11-15, insulative material 57 of insulative islands 55 (neither being shown) has been removed (e.g., by etching) downwardly at least to uppermost surfaces 60 of digitlines 42 in peripheral region 13. In one such embodiment and as shown, the removing is to below uppermost surfaces 60 of digitlines 42 and in one such latter embodiment and as shown is of all insulative material 57 of insulative islands 55. In one embodiment, the removing is of only some (not shown) of insulative material 57 of insulative islands 55.

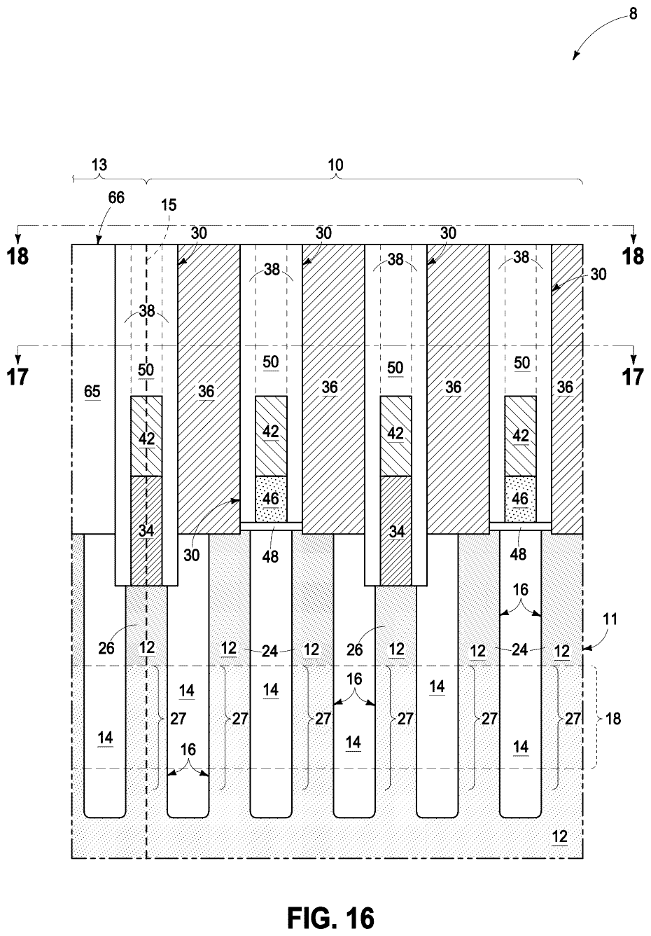

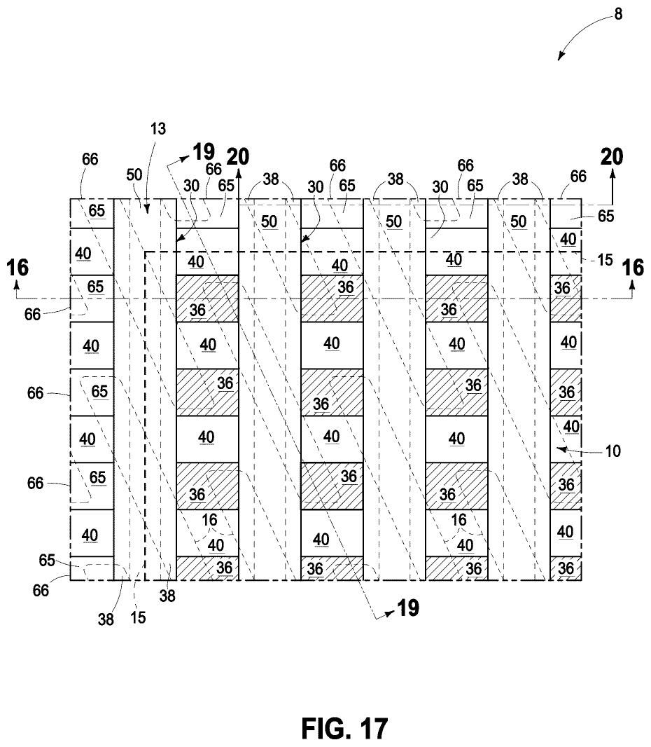

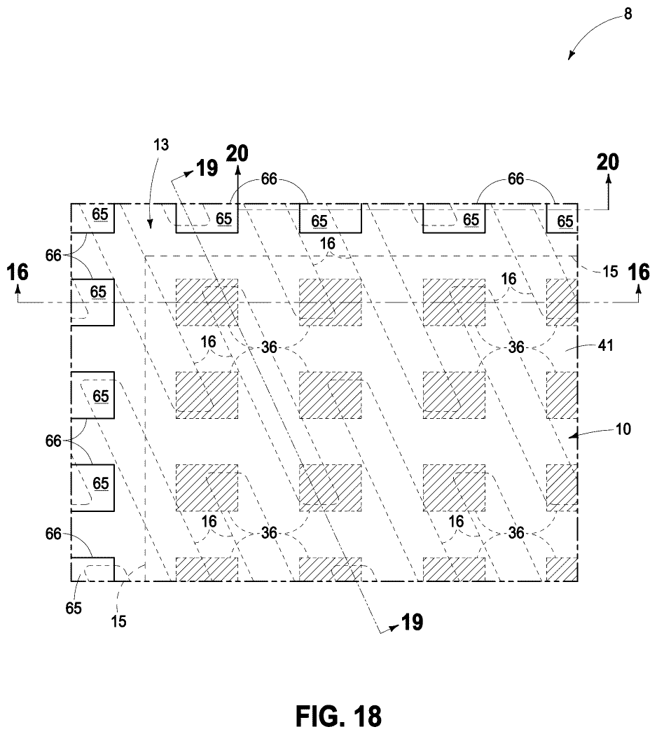

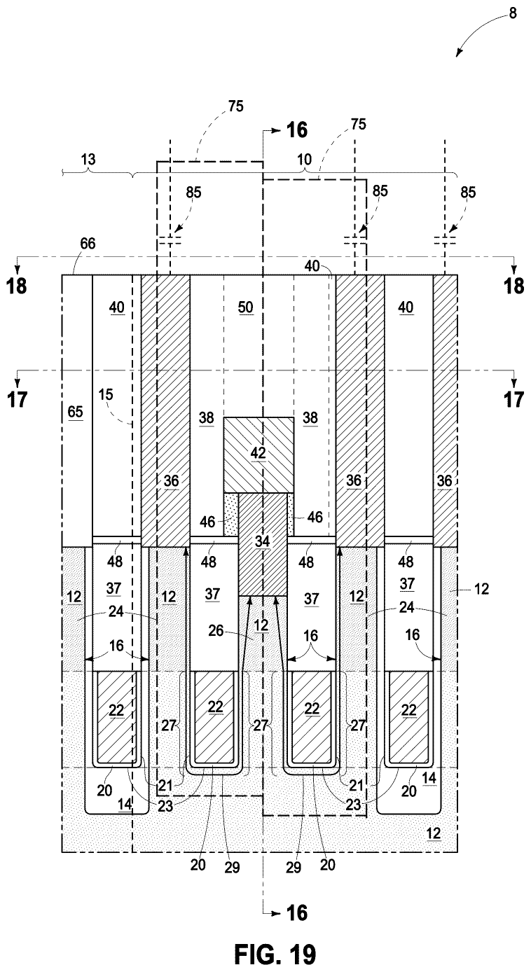

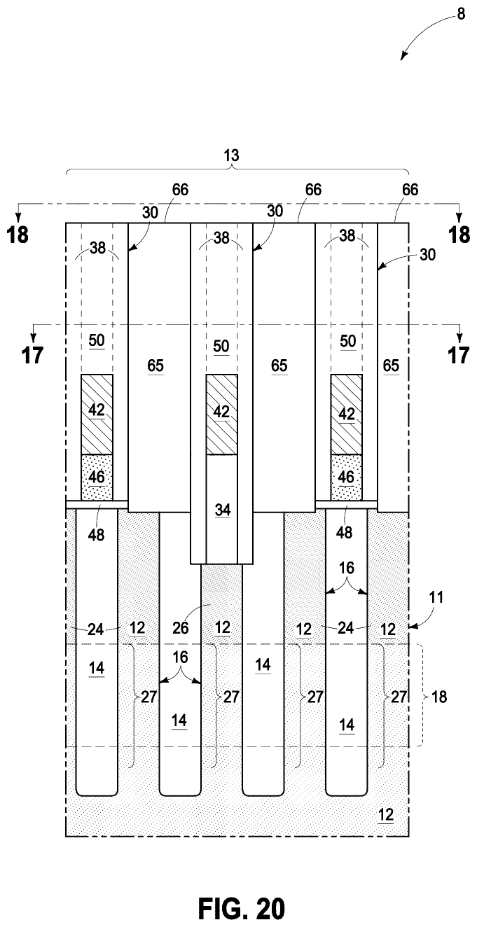

Referring to FIGS. 16-20, insulative material 57 (not shown) that was removed has been replaced with insulator material 65 to form insulator islands 66 in peripheral region 13 that are individually surrounded by insulating material 38/50/40 (e.g., after removing masking material 41 [no longer shown] if such is used). In one embodiment, insulating material 38/50/40 and insulator material 65 are of the same composition relative one another and in another embodiment are of different compositions relative one another.

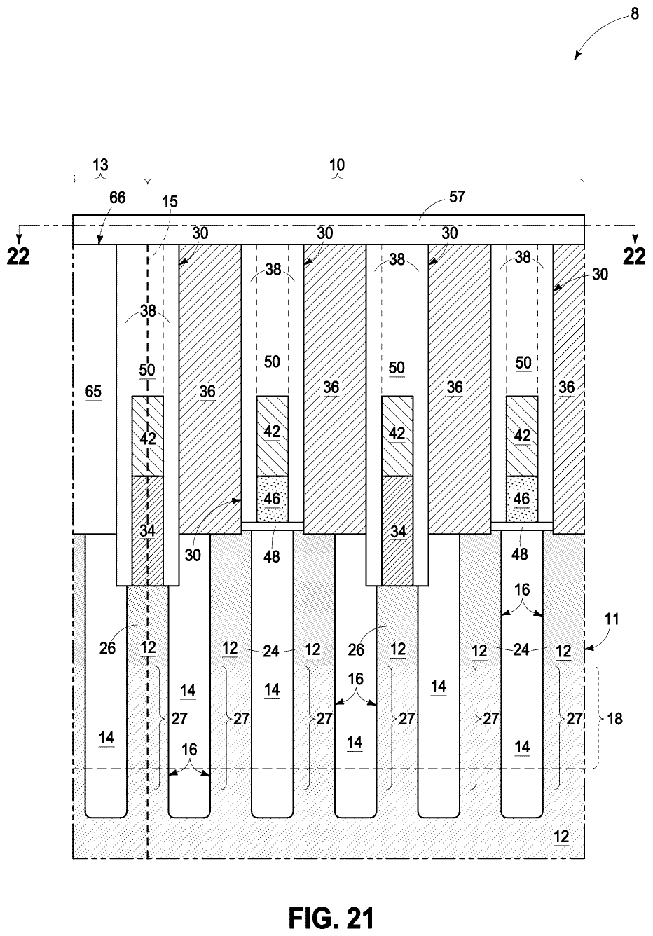

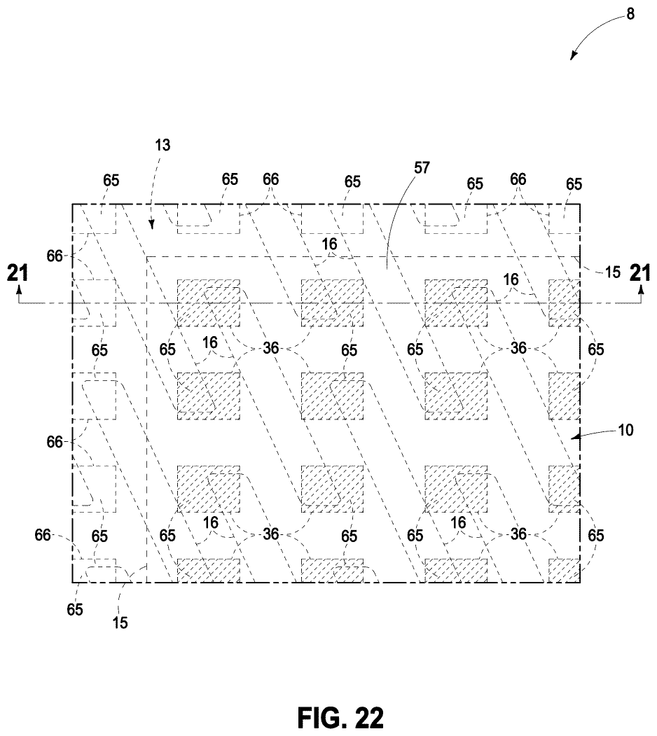

Referring to FIGS. 21 and 22, a layer of insulative material 57 has been formed directly above insulator islands 66 in peripheral region 13 and directly above conductive vias 36 in memory-array region 10. Additional material may be thereatop (e.g., an insulative material of different composition from that of insulative material 57 [e.g., silicon nitride if insulative material 57 is silicon dioxide] and not shown).

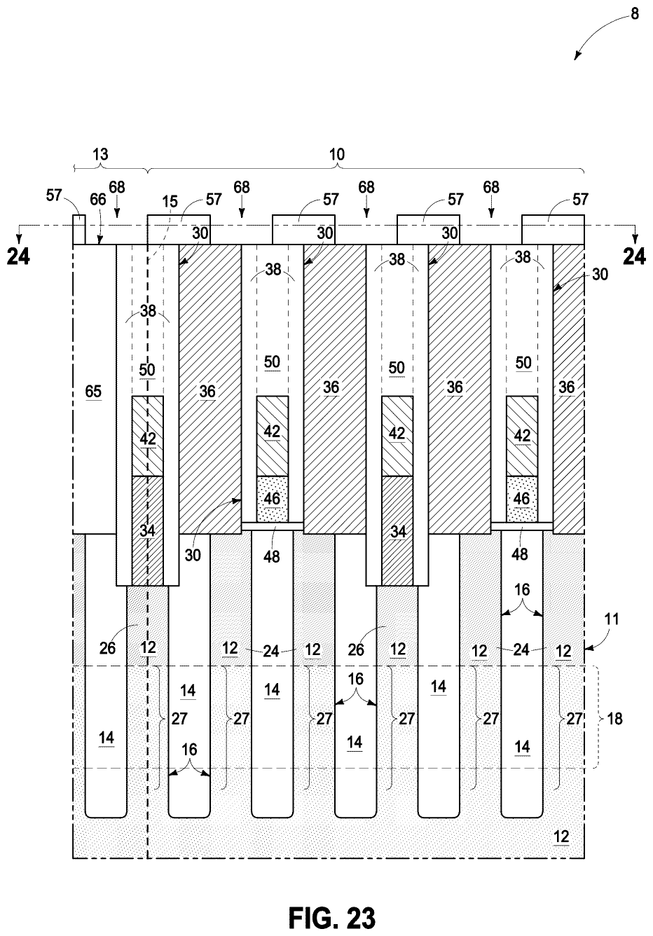

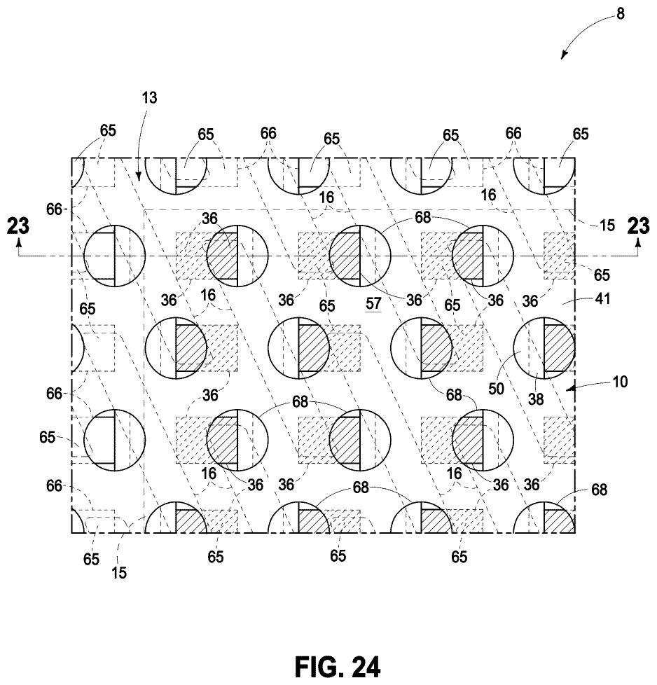

Referring to FIGS. 23 and 24, openings 68 have been etched through the layer of insulative material 57 to insulator islands 66 and conductive vias 36 (e.g., using a photoresist mask [not shown]). Such etching is ideally conducted selectively relative to insulator islands 66 and selectively relative to conductive vias 36.

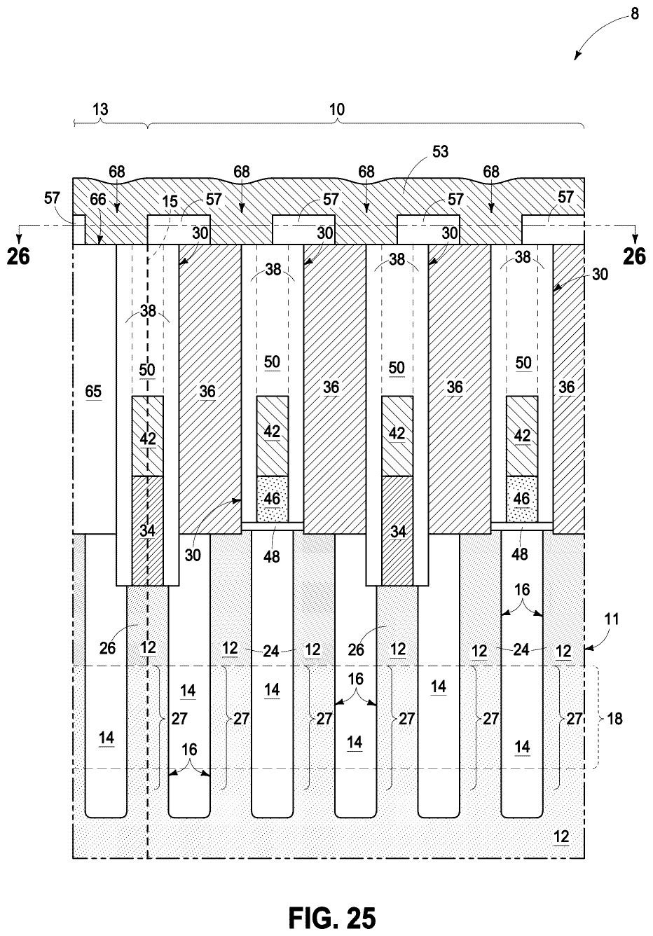

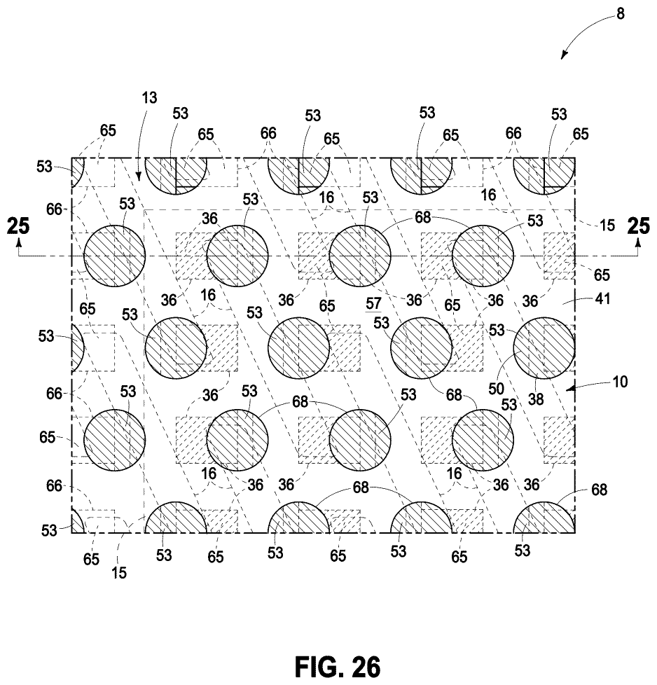

Referring to FIGS. 25 and 26, and in one embodiment, conductive material 53 (e.g., conductive metal material) has been formed in openings 68 (e.g., directly against conductive vias 34 and/or directly against insulator islands 66).

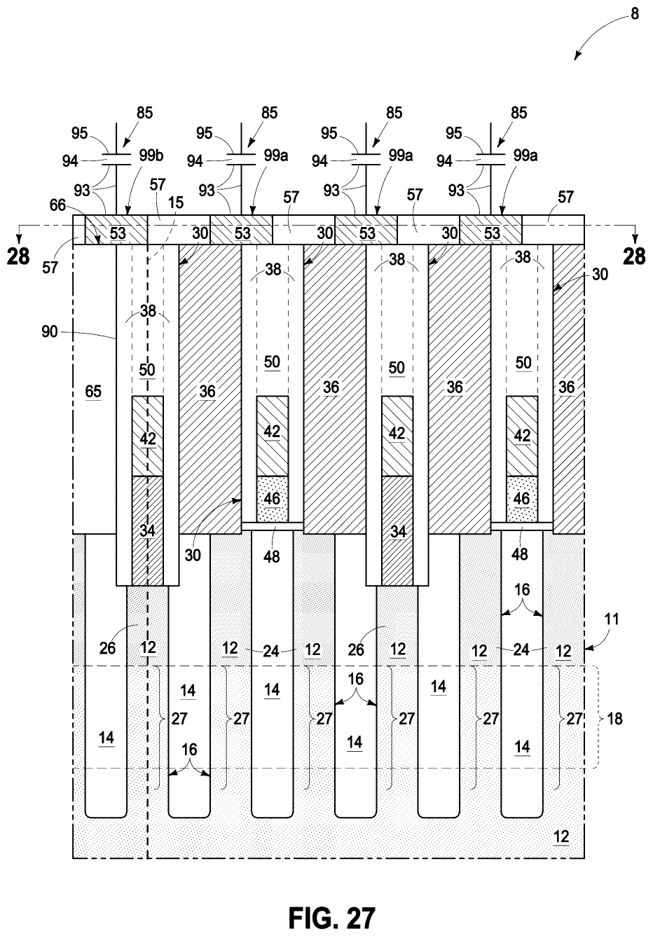

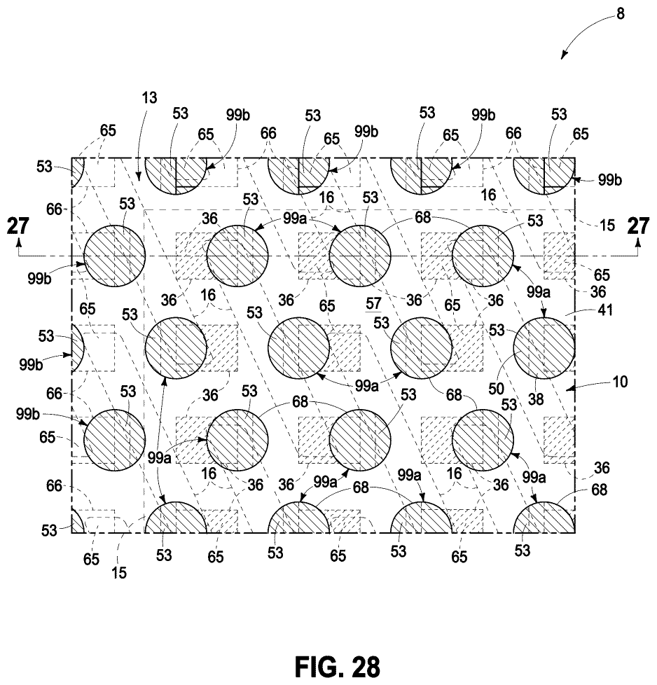

Referring to FIGS. 27 and 28, conductive material 53 has been planarized back thereby forming conducting vias 99*, followed by forming a plurality of capacitors 85 which are largely schematically shown in FIG. 27 (and in FIG. 9) (an * being used as a suffix to be inclusive of all such same-numerically-designated structures or portions thereof that may or may not have other suffixes). Capacitors 85 individually comprise a lower conductive electrode 93, an upper conductive electrode 95, and a capacitor insulator 94 there-between. Individual lower conductive electrodes 93 comprise conductive material 53 in individual openings 68. Conductive material 53 in some embodiments may be considered as a redistribution layer (RDL) (i.e., an upper conductive layer of integrated circuitry that comprises conductive metal material and that makes input/output nodes for the integrated circuitry available in or at other locations).

Any other attribute(s) or aspect(s) as shown and/or described herein with respect to other embodiments may be used.

Heretofore, insulative material 57 that was directly above the source/drain regions of inoperative transistors in the periphery region was of the same composition as that of upper insulative material 57 in which the RDL layer was formed. When openings 68 were etched through upper insulative material 57, such could undesirably etch the insulative material 57 below upper insulative material 57 directly under such openings and expose digitlines 42. This could lead to fatal shorts to digitlines 42 when conductive material 53 was subsequently deposited. Such may be prevented if the underling material (insulator material herein) is of different composition from that of insulative material 57.

Embodiments of the invention encompass a method used in forming integrated circuitry (e.g., that of or comprising construction 8) comprising forming a construction (e.g., 8) comprising operative (e.g., 25) and inoperative (e.g., 17) transistors (e.g., regardless of whether being part of memory circuitry). Conductive vias (e.g., 34) are individually directly above and directly electrically coupled to individual of the operative transistors. Insulative islands (e.g., 55) individually extend upwardly from individual of the inoperative transistors. Insulating material (e.g., 38/50/40) surrounds the insulative islands and the conductive vias. The insulating material is of different composition from that of insulative material (e.g., 57) of the insulative islands. At least some of the insulative material is removed (e.g., by etching) from being atop the insulative islands. The removed insulative material is replaced with insulator material (e.g., 65) to form insulator islands (e.g., 66) that are surrounded by the insulating material. A layer of the insulative material is formed directly above the insulator islands and directly above the conductive vias. Openings (e.g., 68) are etched through the layer of insulative material to the insulator islands and the conductive vias (e.g., ideally selectively relative to the insulator islands and selectively relative to the conductive vias). Any other attribute(s) or aspect(s) as shown and/or described herein with respect to other embodiments may be used.

Embodiments of the invention encompass a method used in forming DRAM circuitry (e.g., that of or comprising construction 8) comprising operative DRAM cells (e.g., within outlines 75) in a memory-array region (e.g., 10) and a peripheral region (e.g., 13) adjacent the memory-array region. Such comprises forming operative DRAM-cell transistors (e.g., 25) within semiconductive material (e.g., 12) of a semiconductive substrate (e.g., 11) in the memory-array region, with an insulative material (e.g., 57) being in the peripheral region. Masking material (e.g., 41) is formed in the memory-array region. The masking material has an opening (e.g., 43) therethrough in the peripheral region that extends to the insulative material. The masking material is directly above the memory-cell transistors in the memory-array region. At least some of the insulative material that is directly under the opening in the masking material in the peripheral region is removed (e.g., by etching) through the opening in the masking material in the peripheral region. All of the masking material is removed after removing the insulative material. After removing all of the masking material, insulator material (e.g., 65) is formed where the removed insulative material was.

In one embodiment, the insulator and insulative materials are of different compositions relative one another and in another embodiment are of the same composition relative one another.

The embodiments shown by FIGS. 1-28 is one such example latter-described embodiment. As an alternate example, consider a memory array region having a peripheral region adjacent thereto, with a shallow trench isolation region comprising insulative material being in the peripheral region. At least some of such insulative material that is directly under an opening in masking material in the shallow trench isolation region in the peripheral region could be removed (e.g., by etching) through the opening in the masking material in the peripheral region. All of the masking material would thereafter be removed. Then, insulator material can be formed where the insulative material was removed from the shallow trench isolation region. Subsequently formed digitlines may be formed directly against the insulator material. The insulator may be chosen such that the digitlines adhere to the insulator material better than would have occurred to the original insulative material.

As an alternate example, consider a memory array region having a peripheral region adjacent thereto, with a shallow trench isolation region comprising insulative material being in the peripheral region. A blanketing conductive material from which digitlines will be formed may be formed in the memory-array and peripheral regions, with the insulative material being directly there-above. Such insulative material and conductive material that is directly under an opening in masking material in the peripheral region near where a terminus of the digitlines will be above the shallow trench isolation regions could be removed (e.g., by etching) through the opening in the masking material in the peripheral region. All of the masking material would thereafter be removed. Then, insulator material can be formed where the removed insulative material and conductive material were. Such would be followed by patterning the conductive material to form the digitlines. Such a method may be used to preclude longitudinal erosion of the conductive material at the end of the digitlines when such conductive material is patterned to form the digitlines.

Any other attribute(s) or aspect(s) as shown and/or described herein with respect to other embodiments may be used.

Alternate embodiment constructions may result from method embodiments described above, or otherwise. Regardless, embodiments of the invention encompass integrated circuitry independent of method of manufacture. Nevertheless, such circuitry may have any of the attributes as described herein in method embodiments. Likewise, the above-described method embodiments may incorporate, form, and/or have any of the attributes described with respect to structure embodiments.

In one embodiment, an integrated circuit construction (e.g., that of or comprising construction 8) comprises operative and inoperative transistors (e.g., 25 and 17, respectively). Conductive vias (e.g., 36) are individually directly above and directly electrically coupled to individual of the operative transistors. Insulator islands (e.g., 66) individually extend upwardly from individual of the inoperative transistors. Insulating material (e.g., 38/58/40) surrounds individual of the insulator islands and individual of the conductive vias. Insulative material (e.g., 57) is directly above the insulating material. Conducting vias (e.g., 99*) individually extend through the insulative material. Some of the conducting vias (e.g., 99a) are directly above and directly against individual of the conductive vias. Another some of the conducting vias (e.g., 99b) are directly above individual of the insulator islands.

In one embodiment, the insulating material and the insulative material are of different compositions relative one another. In one embodiment, the insulating material and insulator material (e.g., 65) of the insulator islands are of the same composition relative one another, with an interface 90 (FIG. 27) of the insulating material and the insulator islands being perceptible in spite of the insulating material and the insulator materials being of the same composition relative one another. In one embodiment, the another some of the conducting vias are directly against the insulator islands.

Any other attribute(s) or aspect(s) as shown and/or described herein with respect to other embodiments may be used.

In one embodiment, DRAM circuitry (e.g., that of or comprising construction 8) comprises operative DRAM-cell transistors (e.g., 25) within semiconductive material (e.g., 12) of a semiconductive substrate (e.g., 11) in a memory-array region (e.g., 10) and inoperative transistors (e.g., 17) in a peripheral region (e.g., 13) that is adjacent the memory-array region. Digitlines (e.g., 42) are individually directly above and directly electrically coupled to one (e.g., 26) of two source/drain regions (e.g., 24, 26) of multiple of the operative DRAM-cell transistors. The digitlines extend from the memory-array region into the peripheral region and are directly above the inoperative transistors. Conductive vias (e.g., 36) are individually directly above and directly electrically coupled to the other (e.g., 24) of the two source/drain regions of one of the operative DRAM-cell transistors in the memory-array region. Insulator islands (e.g., 66) individually extend upwardly from individual of the inoperative transistors to above and aside the digitlines in the peripheral region. Insulating material (e.g., 38/50/40) surrounds individual of the insulator islands and individual of the conductive vias. Insulative material (e.g., 57) is directly above the insulating material. Conducting vias (e.g., 99*) individually extend through the insulative material. Some of the conducting vias (e.g., 99a) are directly above and directly against individual of the conductive vias. Another some (e.g., 99b) of the conducting vias are directly above individual of the insulator islands.

Any other attribute(s) or aspect(s) as shown and/or described herein with respect to other embodiments may be used.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The circuitry described herein (e.g., conductive vias thereof) may connect with circuitry that is on either the top or the bottom (i.e., either z-axis side) of a vertical stack regardless of orientation of the construction in three-dimensional space and which is not material to aspects of the inventions disclosed herein. For example, and by way of example only, conductive vias may connect with peripheral control circuitry that is beneath the stack with respect to the orientation shown in the drawings. As an alternate example, and by way of example only, conductive vias may connect with peripheral control circuitry that is above the stack with respect to the shown orientation, for example to another substrate having such circuitry and that is bonded with the top of the stack with respect to the shown orientation. In such alternate example, the construction may be inverted from the shown orientation and then bonded with the other substrate. Further, in such alternate example, electronic components may be fabricated relative to the bottom of the stack with respect to the shown orientation but inverted therefrom during processing. Such electronic components may connect with conductive vias that extend through the stack to the substrate bonded with the other side that has such peripheral control circuitry. Regardless, constructions as shown and described herein may be processed, packaged, and/or mounted in any three-dimensional spatial orientation.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication and as shown in drawings (if any) herein. Further, “vertical” and “horizontal” as used herein are generally perpendicular directions relative one another and independent of orientation of the substrate in three-dimensional space during fabrication and/or in a finished construction. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90°or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a method used in forming integrated circuitry comprises forming a construction comprising operative and inoperative transistors. Conductive vias are individually directly above and directly electrically coupled to individual of the operative transistors. Insulative islands individually extend upwardly from individual of the inoperative transistors. Insulating material surrounds individual of the insulative islands and individual of the conductive vias. The insulating material is of different composition from that of insulative material of the insulative islands. At least some of the insulative material is removed from being atop the insulative islands. The removed insulative material is replaced with insulator material to form insulator islands that are surrounded by the insulating material. A layer of the insulative material is formed directly above the insulator islands and directly above the conductive vias. Openings are etched through the layer of insulative material to the insulator islands and the conductive vias.

In some embodiments, a method used in forming DRAM circuitry comprising a memory-array region and a peripheral region adjacent the memory-array region comprises forming a construction comprising operative DRAM-cell transistors within semiconductive material of a semiconductive substrate in the memory-array region and inoperative transistors in the peripheral region. Digitlines are directly above and individually directly electrically coupled to one of two source/drain regions of multiple of the operative DRAM-cell transistors. The digitlines extend from the memory-array region into the peripheral region and are directly above the inoperative transistors. Conductive vias are individually directly above and directly electrically coupled to the other of the two source/drain regions of one of the operative DRAM-cell transistors in the memory-array region. Insulative islands are in the peripheral region and individually extend from directly above individual of the inoperative transistors to above and aside the digitlines in the peripheral region. Insulating material surrounds individual of the insulative islands and individual of the conductive vias. The insulating material is of different composition from that of insulative material of the insulative islands. The insulative material of the insulative islands is removed downwardly at least to uppermost surfaces of the digitlines in the peripheral region. The removed insulative material is replaced with insulator material to form insulator islands in the peripheral region that are surrounded by the insulating material. A layer of the insulative material is formed directly above the insulator islands in the peripheral region and directly above the conductive vias in the memory-array region. Openings are etched through the layer of insulative material to the insulator islands and the conductive vias.

In some embodiments, a method used in forming DRAM circuitry comprising operative DRAM cells in a memory-array region and a peripheral region adjacent the memory-array region comprises forming operative DRAM-cell transistors within semiconductive material of a semiconductive substrate in the memory-array region. An insulative material is in the peripheral region. Masking material is formed in the memory-array region. The masking material has an opening therethrough in the peripheral region that extends to the insulative material. The masking material is directly above the memory-cell transistors in the memory-array region. At least some of the insulative material that is directly under the opening in the masking material in the peripheral region is removed through the opening in the masking material in the peripheral region. All of the masking material is removed after removing the insulative material. After removing all of the masking material, insulator material is formed where the removed insulative material was.

In some embodiments, an integrated circuit construction comprises operative and inoperative transistors. Conductive vias are individually directly above and directly electrically coupled to individual of the operative transistors. Insulator islands individually extend upwardly from individual of the inoperative transistors. Insulating material surrounds individual of the insulator islands and individual of the conductive vias. Insulative material is directly above the insulating material. Conducting vias individually extend through the insulative material. Some of the conducting vias are directly above and directly against individual of the conductive vias. Another some of the conducting vias are directly above individual of the insulator islands.

In some embodiments, DRAM circuitry comprises operative DRAM-cell transistors within semiconductive material of a semiconductive substrate in a memory-array region and inoperative transistors in a peripheral region that is adjacent the memory-array region. Digitlines are individually directly above and directly electrically coupled to one of two source/drain regions of multiple of the operative DRAM-cell transistors. The digitlines extend from the memory-array region into the peripheral region and are directly above the inoperative transistors. Conductive vias are individually directly above and directly electrically coupled to the other of the two source/drain regions of one of the operative DRAM-cell transistors in the memory-array region. Insulator islands individually extend upwardly from individual of the inoperative transistors to above and aside the digitlines in the peripheral region. Insulating material surrounds individual of the insulator islands and individual of the conductive vias. Insulative material is directly above the insulating material. Conducting vias individually extend through the insulative material. Some of the conducting vias are directly above and directly against individual of the conductive vias. Another some of the conducting vias are directly above individual of the insulator islands.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming integrated circuitry, comprising:
forming a construction comprising operative and inoperative transistors, conductive vias individually being directly above and directly electrically coupled to individual of the operative transistors, insulative islands that individually extend upwardly from individual of the inoperative transistors, insulating material surrounding individual of the insulative islands and individual of the conductive vias, the insulating material being of different composition from that of insulative material of the insulative islands;
removing at least some of the insulative material from being atop the insulative islands;
replacing the removed insulative material with insulator material to form insulator islands that are surrounded by the insulating material;
forming a layer of the insulative material directly above the insulator islands and directly above the conductive vias; and
etching openings through the layer of insulative material to the insulator islands and the conductive vias.

2. The method of claim 1 wherein the etching is selectively relative to the insulator islands and selective relative to the conductive vias.

3. The method of claim 1 wherein the insulative material is silicon dioxide and the insulating material is silicon nitride.

4. The method of claim 1 wherein the removing is of only some of the insulative material of the insulative islands.

5. The method of claim 1 wherein the removing is of all of the insulative material of the insulative islands.

6. The method of claim 1 wherein the insulating material and the insulator material are of the same composition relative one another.

7. The method of claim 1 wherein the insulating material and the insulator material are of the different compositions relative one another.

8. The method of claim 1 comprising forming conductive material in the openings after the etching.

9. The method of claim 8 wherein the conductive material is formed directly against the insulator islands and the conductive vias.

10. A method used in forming DRAM circuitry comprising a memory-array region and a peripheral region adjacent the memory-array region, comprising:
forming a construction comprising operative DRAM-cell transistors within semiconductive material of a semiconductive substrate in the memory-array region and inoperative transistors in the peripheral region, digitlines being directly above and individually directly electrically coupled to one of two source/drain regions of multiple of the operative DRAM-cell transistors, the digitlines extending from the memory-array region into the peripheral region and being directly above the inoperative transistors, conductive vias individually being directly above and directly electrically coupled to the other of the two source/drain regions of one of the operative DRAM-cell transistors in the memory-array region, insulative islands being in the peripheral region that individually extend from directly above individual of the inoperative transistors to above and aside the digitlines in the peripheral region, insulating material surrounding individual of the insulative islands and individual of the conductive vias, the insulating material being of different composition from that of insulative material of the insulative islands;
removing the insulative material of the insulative islands downwardly at least to uppermost surfaces of the digitlines in the peripheral region;
replacing the removed insulative material with insulator material to form insulator islands in the peripheral region that are surrounded by the insulating material;
forming a layer of the insulative material directly above the insulator islands in the peripheral region and directly above the conductive vias in the memory-array region; and
etching openings through the layer of insulative material to the insulator islands and the conductive vias.

11. The method of claim 10 wherein the etching is selectively relative to the insulator islands and selective relative to the conductive vias.

12. The method of claim 10 wherein the removing is of only some of the insulative material of the insulative islands.

13. The method of claim 10 wherein the removing is downwardly to below the uppermost surfaces of the digitlines in the peripheral region.

14. The method of claim 13 wherein the removing is of only some of the insulative material of the insulative islands.

15. The method of claim 13 wherein the removing is of all of the insulative material of the insulative islands.

16. The method of claim 10 wherein the insulating material and the insulator material are of the same composition relative one another.

17. The method of claim 10 wherein the insulating material and the insulator material are of the different compositions relative one another.

18. The method of claim 10 comprising forming conductive material in the openings after the etching.

19. The method of claim 18 wherein the conductive material is formed directly against the insulator islands and the conductive vias.

20. A method used in forming DRAM circuitry comprising operative DRAM cells in a memory-array region and a peripheral region adjacent the memory-array region, comprising:
forming operative DRAM-cell transistors within semiconductive material of a semiconductive substrate in the memory-array region, an insulative material being in the peripheral region;
forming masking material in the memory-array region, the masking material having an opening therethrough in the peripheral region that extends to the insulative material, the masking material being directly above the memory-cell transistors in the memory-array region;
removing at least some of the insulative material that is directly under the opening in the masking material in the peripheral region through the opening in the masking material in the peripheral region;
removing all of the masking material after removing the insulative material; and
after removing all of the masking material, forming insulator material where the removed insulative material was.

21-29. (canceled)

30. An integrated circuit construction comprising:
operative and inoperative transistors;
conductive vias that are individually directly above and directly electrically coupled to individual of the operative transistors;
insulator islands that individually extend upwardly from individual of the inoperative transistors;
insulating material surrounding individual of the insulator islands and individual of the conductive vias;
insulative material directly above the insulating material; and
conducting vias individually extending through the insulative material, some of the conducting vias being directly above and directly against individual of the conductive vias, another some of the conducting vias being directly above individual of the insulator islands.

31-34. (canceled)

35. DRAM circuitry comprising:
operative DRAM-cell transistors within semiconductive material of a semiconductive substrate in a memory-array region and inoperative transistors in a peripheral region that is adjacent the memory-array region;
digitlines that are individually directly above and directly electrically coupled to one of two source/drain regions of multiple of the operative DRAM-cell transistors, the digitlines extending from the memory-array region into the peripheral region and being directly above the inoperative transistors;
conductive vias that are individually directly above and directly electrically coupled to the other of the two source/drain regions of one of the operative DRAM-cell transistors in the memory-array region;
insulator islands that individually extend upwardly from individual of the inoperative transistors to above and aside the digitlines in the peripheral region;
insulating material surrounding individual of the insulator islands and individual of the conductive vias;
insulative material directly above the insulating material; and
conducting vias individually extending through the insulative material, some of the conducting vias being directly above and directly against individual of the conductive vias, another some of the conducting vias being directly above individual of the insulator islands.

36-38. (canceled)
